(19) United States
(12) Patent Application Publication
(10) Pub. No.: US 2017/0349000 A1
(43) Pub. Date: Dec. 7, 2017

(54) DECORATIVE ITEM, DECORATIVE ITEM UNIT AND METHOD OF MANUFACTURING DECORATIVE ITEM

(71) Applicant: FUJITSU COMPONENT LIMITED, Tokyo (JP)

(72) Inventor: Hiroki SATO, Tokyo (JP)

(21) Appl. No.: 15/533,425

(22) PCT Filed: Oct. 22, 2015
(86) PCT No.: PCT/JP2015/079790

§ 371 Date: Jun. 6, 2017

(30) Foreign Application Priority Data
Dec. 17, 2014 (JP) 2014-254990

(51) Int. Cl. B44C 1/00; B23K 26/00; B44C 1/22; C23C 16/02

(52) U.S. Cl. CPC B44C 1/005; C23C 16/0227; B23K 26/0078; B44C 1/228

(57) ABSTRACT

A decorative item includes a base body; a decorative portion formed by roughing a surface of the base body; and a coating layer that covers the surface of the base body including the decorative portion.

### BACKGROUND OF THE INVENTION

### 1. Field of the Invention

The present invention relates to a decorative item, a decorative item unit and a method of manufacturing a decorative item.

### 2. Description of the Related Art

For example, for forming various different patterns on surfaces of items that are mass produced by dies or the like, it is necessary to manufacture a plurality of dies in accordance with the number of patterns. Thus, there is a problem that manufacturing cost is increased.

Thus, a method of forming items having various patterns by in-mold shaping is disclosed in which a film with a pattern is placed in a die (see Patent Document 1, for example). According to such a method, it is possible to mass produce items having various patterns by a single die facility.

### PATENT DOCUMENT

[Patent Document 1] Japanese Laid-open Patent Publication No. 2006-187938

However, according to the above method of Patent Document 1, a step of forming a film with a pattern, a step of placing the film with the pattern in a die, a step of removing the film with the pattern from the item after in-mold shaping and the like are necessary. Thus, there is a risk that manufacturing steps are complicated and manufacturing cost cannot be reduced.

### SUMMARY OF THE INVENTION

According to an aspect of the embodiment, there is provided a decorative item including a base body; a decorative portion formed by roughing a surface of the base body; and a coating layer that covers the surface of the base body including the decorative portion.

According to the embodiment, a decorative item is provided on a surface of which a pattern is formed by a simple method.

### BRIEF DESCRIPTION OF THE DRAWINGS

FIG. 1 is a perspective view illustrating an example of a decorative item of an embodiment;

FIG. 2 is a schematic cross-sectional view taken along an A-A line of FIG. 1;

FIG. 3 is a view illustrating an example of a keyboard of the embodiment; and

FIG. 4 is a flowchart illustrating a method of manufacturing the decorative item of the embodiment.

### DETAILED DESCRIPTION OF THE PREFERRED EMBODIMENTS

The invention will be described herein with reference to illustrative embodiments. The invention will be described herein with reference to illustrative embodiments. It is to be noted that, in the explanation of the drawings, the same components are given the same reference numerals, and explanations are not repeated.

### (Decorative Item)

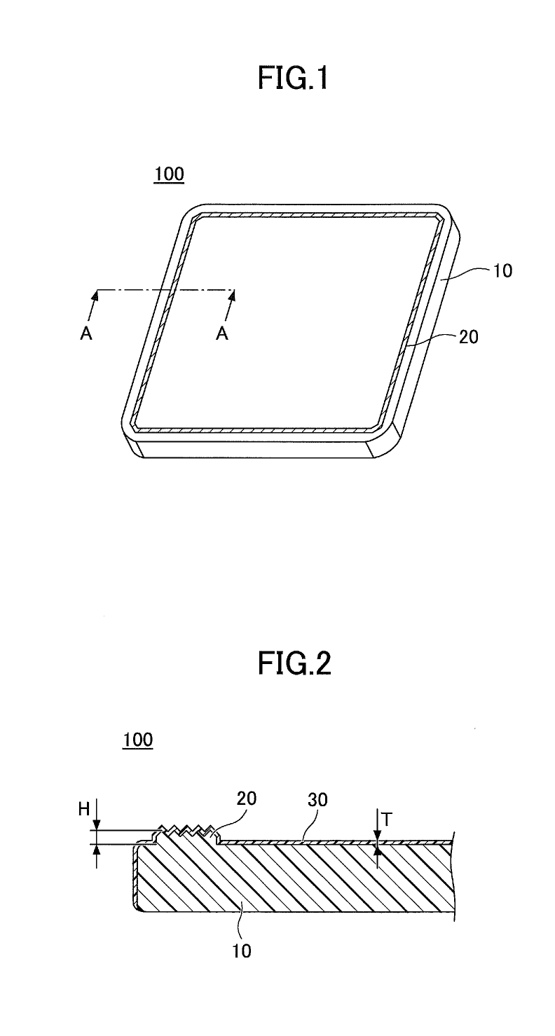

FIG. 1 is a perspective view illustrating an example of a decorative item 100 of an embodiment. FIG. 2 is a schematic cross-sectional view taken along an A-A line of FIG. 1.

As illustrated in FIG. 1 and FIG. 2, the decorative item 100 includes a base body 10, a decorative portion 20 formed at a surface of the base body 10 and a coating layer 30 (not illustrated in FIG. 1) that covers the surface of the base body 10 including the decorative portion 20.

The base body 10 is a resin item having a rectangular plate shape, and is formed using a die or the like, for example. In this embodiment, the surface of the base body 10 is a smooth surface without a recess and a projection. The surface of the base body 10 may be a polished surface, for example.

The base body 10 is not limited to resin, and may be formed using a material such as a metal, for example. Further, the shape of the base body 10 is not limited to the illustrated example, and the base body 10 may have a selectable shape such as a rectangular box shape, a cylindrical shape or a spherical shape, for example.

The decorative portion 20 is a portion obtained by roughing the surface of the base body 10 by laser processing. For example, by irradiating YAG laser, CO₂ laser or the like on the surface of the base body 10, the surface of the base body 10 is roughed to form the decorative portion 20. As illustrated in FIG. 2, the decorative portion 20 includes fine recesses and projections at the surface. The surface roughness (arithmetic mean roughness Ra) of the decorative portion 20 is formed to be greater than the surface roughness of the smooth surface of the base body 10 at which the decorative portion 20 is not formed. Although the decorative portion 20 has a frame shape that rims the surface of the base body 10 according to the embodiment, the decorative portion 20 may have a different shape such as shaping a character, a graphic or a pattern, for example.

Further, as illustrated in FIG. 2, the decorative portion 20 is formed to be risen from the surface of the base body 10. As such, by forming the decorative portion 20 to be risen from the surface of the base body 10, visibility of the character, the graphic, the pattern or the like formed by the decorative portion 20 is improved. However, the decorative portion 20 may be formed into a groove concaved from the surface of the base body 10 by grinding the base body 10 by laser processing.

As illustrated in FIG. 2, a coating material is coated on the surface of the base body 10 including the decorative portion 20 to form the coating layer 30. By coating the surface of the base body 10, the smooth surface of the base body 10 other than the decorative portion 20 becomes a glossy coated surface, and the roughed decorative portion 20 becomes a frosting coated surface. As such, by varying the roughness of the smooth surface of the base body 10 and the roughness of the decorative portion 20, a difference is generated in reflection of light between the parts and the decorative portion 20 can be easily recognized.

As illustrated in FIG. 2, the coating layer 30 is formed by coating a coating material so as to cover the surface of the base body 10 including the decorative portion 20. It is preferable that the coating layer 30 is formed such that a difference in glossiness between the surface of the base body 10 and the decorative portion 20 is easily generated and the visibility of the decorative portion 20 is improved. The coating layer 30 may be formed by, for example, a coating material having a glossy color such as silver, but may be formed by a coating material of different colors.

The coating layer 30 is formed by, for example, using an acrylic resin-based coating material or an urethane resin-based coating material, but a coating material of different materials may be used. Further, the coating layer 30 may be formed by, for example, laminating a colored film or the like on the surface of the base body 10.

If the coating layer 30 is too thick, the recesses and projections at the surface of the decorative portion 20 are filled to be smooth, and the difference in roughness between the surface of the base body 10 is decreased to lower visibility of the decorative portion. Thus, it is preferable that the coating layer 30 is formed as thin as possible.

As described above, a character, a graphic or the like is formed on the surface of the decorative item 100 by, for example, providing the decorative portion 20 of a selectable shape such as a character, a graphic or the like on the surface of the base body 10 that is mass produced using a single die by laser processing, for example. Thus, it is unnecessary to manufacture a plurality of dies or the like in accordance with the patterns, and it is possible to form the decorative items 100 having various patterns by a simple method with low cost.

### (Decorative Item Unit)

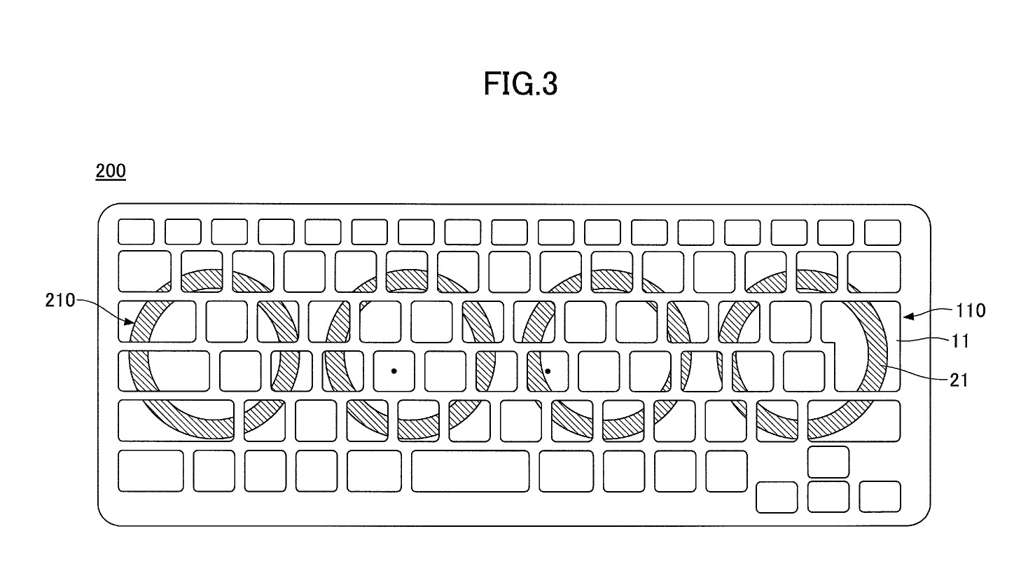

FIG. 3 is a view illustrating an example of a keyboard 200, as a decorative item unit including a plurality of the decorative items.

The keyboard 200 is an example of a decorative item unit, and includes a plurality of key-tops 110 on which different patterns are formed, respectively. The key-tops 110 are an example of the decorative items, and the decorative portions 21 of different patterns are formed at the surfaces of the base bodies 11 made of resin, respectively. A character, a graphic or the like that is not illustrated in FIG. 3 may be formed on the key-top 110 as the decorative portion 21.

As illustrated in FIG. 3, by placing the key-tops 110 each having the decorative portion 21 of a predetermined shape at predetermined positions, respectively, a pattern 210 is formed in the keyboard 200 by a combination of the plurality of the decorative portions 21.

For an example illustrated in FIG. 3, the pattern 210 in which circle patterns are aligned in a lateral direction is formed. Alternatively, a pattern of a selectable shape may be formed by placing the key-tops 110 having the decorative portions 21 of shapes different from those of FIG. 3.

Although the keyboard 200 including the plurality of key-tops 110, as the decorative items, is exemplified as the decorative item unit in which a pattern is formed by a combination of the decorative portions of the plurality of decorative items, the decorative item unit is not limited so.

For such a decorative item unit, for example, a calculator, a mobile phone, an operation panel or the like including a plurality of buttons or the like as the decorative items may be used. By forming decorative portions of predetermined shapes to a plurality of buttons or the like as the decorative items, and placing the buttons at predetermined positions, respectively, to form a pattern by a combination of the decorative portions, it is possible to increase design of a product as the decorative item unit.

### (Method of Manufacturing Decorative Item)

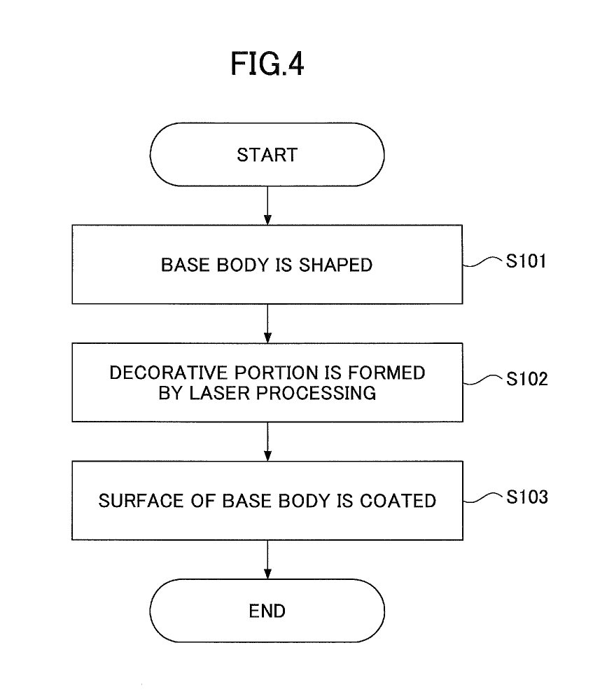

FIG. 4 is a view illustrating an example of a flowchart of a method of manufacturing the decorative item 100 of the embodiment.

According to the method of manufacturing the decorative item 100 of the embodiment, as illustrated in FIG. 4, first, in step S101, the base body 10 is shaped. When the base body 10 is resin, the base body 10 is shaped using a die or the like, for example. Alternatively, when the base body 10 is a metal or the like, the base body 10 is shaped by cutting or the like, for example. A surface treatment such as polishing may be performed on the base body 10 after the base body 10 is shaped, for example.

Next, in step S102, the decorative portion 20 is formed on the surface of the base body 10 by laser processing. Subsequently, in step S103, the coating layer 30 is formed by coating the surface of the base body 10 including the decorative portion 20.

According to the above described method of manufacturing the decorative item 100, for example, by forming the decorative portions 20 of different shapes on the surfaces of the base bodies 10 that are mass produced using a single die, it is possible to easily manufacture the decorative items 100 having various patterns with low cost.

As described above, according to the embodiment, as the decorative portion of a selectable shape can be formed by laser processing, it is possible to manufacture decorative items having various patterns by a simple method with low cost. Further, for the decorative item unit in which a plurality of the decorative items having the decorative portions of different shapes are placed at predetermined positions, respectively, it is possible to form various patterns by combinations of the plurality of decorative portions and design is improved.

Although a preferred embodiment of the decorative item, the decorative item unit and the method of manufacturing the decorative item has been specifically illustrated and described, it is to be understood that minor modifications may be made therein without departing from the spirit and scope of the invention as defined by the claims.

The present application is based on and claims the benefit of priority of Japanese Priority Application No. 2014-254990 filed on December 17, 2014, the entire contents of which are hereby incorporated by reference.

### NUMERALS

10, 11 base body
20, 21 decorative portion
30 coating layer
100 decorative item
110 key-top (decorative item)
200 keyboard (decorative item unit)
210 pattern

What is claimed is:

1. A decorative item comprising:
a base body;
a decorative portion formed by roughing a surface of the base body; and
a coating layer that covers the surface of the base body including the decorative portion.

2. A decorative item unit comprising:
a plurality of the decorative items of claim 1.

3. A method of manufacturing a decorative item, comprising:
a laser processing step of roughing a surface of a base body by laser processing to form a decorative portion; and
a coating step of forming a coating layer that covers the surface of the base body including the decorative portion.
